(19) United States
(12) Patent Application Publication
(10) Pub. No.: US 2012/0224301 A1
(43) Pub. Date: Sep. 6, 2012

(54) SLIDABLE AND ROTATABLE PORTABLE ELECTRONIC DEVICE FOR ALIGNING THE SURFACES OF THE KEYPAD AND DISPLAY PORTIONS

(76) Inventor: Albert Murray Pegg, Cambridge (CA)

(21) Appl. No.: 13/040,521

(22) Filed: Mar. 4, 2011

(51) Int. Cl. H05K 7/00; E05D 7/00

(52) U.S. Cl. 361/679.01; 16/362

(57) ABSTRACT

A portable electronic device, including a first portion having a first surface, a second portion having a second surface, and a slide portion coupled to the first and second portions. The first portion, second portion and slide portion are adapted so that the first portion can rotate between a closed position wherein the first portion at least partially covers the second surface, and a rotated position wherein the second surface is at least partially exposed, and wherein, when the first portion is in the rotated position, the first portion and slide portion can slide relative to the second portion along a slide direction to an open position in which the first surface and second surface are aligned.

### FIELD

Embodiments herein relate to portable electronic devices, and more particularly to slidable and rotatable portable electronic devices having a display portion and keypad portion movable between a closed position and an open position.

### INTRODUCTION

Electronic devices, including portable electronic devices, have gained widespread use and may provide a variety of functions including, for example, telephonic, electronic text messaging and other personal information manager (PIM) application functions. Portable electronic devices can include mobile stations such as simple cellular phones, smart phones, Personal Digital Assistants (PDAs), tablets and laptop computers.

Some handheld devices are touch-sensitive devices having a display, such as a liquid crystal display (LCD), with a touch-sensitive overlay. These touch sensitive devices may be useful, as handheld devices tend to be small and therefore limited in space available for user input and output devices. Further, these touch-sensitive devices allow a variety of input and output configurations, for example, because the screen content on the touch-sensitive devices may change depending on the functions and operations being performed.

### BRIEF DESCRIPTION OF THE DRAWINGS

Embodiments of the present disclosure will now be described, by way of example only, with reference to the attached figures, wherein:

FIG. 1 is a simplified block diagram of components of a portable electronic device;

FIG. 2 is a front view of a portable electronic device according to one embodiment shown in a closed position;

FIG. 3 is a front view of the portable electronic device of FIG. 2 shown in an open position;

FIG. 4 is a side view of the portable electronic device of FIG. 2 shown in the closed position;

FIG. 5 is a side view of the portable electronic device of FIG. 2 shown in the open position;

FIG. 6 is a top view of the portable electronic device of FIG. 2 shown in the closed position;

FIG. 7 is a top view of the portable electronic device of FIG. 2 shown in the open position;

FIG. 8 is a front view of a portable electronic device according to another embodiment shown in a closed position;

FIG. 9 is a front view of the portable electronic device of FIG. 8 shown in an open position;

FIG. 10 is a top view of the portable electronic device of FIG. 8 shown in the closed position; and

FIG. 11 is a top view of the portable electronic device of FIG. 8 shown in the open position.

### DETAILED DESCRIPTION

Described herein are various portable electronic devices that may include a touch-sensitive display disposed on a first portion, a keypad disposed on a second portion, a third portion that couples the first and second portions together, and functional components such as a memory and a processor.

It will be appreciated that for simplicity and clarity of illustration, where considered appropriate, reference numerals may be repeated among the figures to indicate corresponding or analogous elements. In addition, numerous specific details are set forth in order to provide a thorough understanding of the example embodiments described herein. However, it will be understood by those of ordinary skill in the art that the example embodiments described herein may be practiced without these specific details. In other instances, well-known methods, procedures and components have not been described in detail so as not to obscure the example embodiments described herein. Also, the description is not to be considered as limited to the scope of the example embodiments described herein.

According to one aspect there is provided a portable electronic device, comprising a first portion having a first surface, a second portion having a second surface, and a slide portion coupled to the first and second portions, wherein the first portion, second portion and slide portion are adapted so that the first portion can rotate between a closed position wherein the first portion at least partially covers the second surface, and a rotated position wherein the second surface is at least partially exposed, and wherein, when the first portion is in the rotated position, the first portion and slide portion can slide relative to the second portion along a slide direction to an open position in which the first surface and second surface are aligned.

According to another aspect, there is provided a method of opening a portable electronic device, comprising providing a first portion having a first surface, a second portion having a second surface, and a slide portion coupled to the first and second portions, rotating the first portion between a closed position wherein the first portion at least partially covers the second surface and a rotated position wherein the second surface is at least partially exposed, and from the rotated position, sliding the first portion and slide portion relative to the second portion along a slide direction to an open position in which the first surface and second surface are aligned.

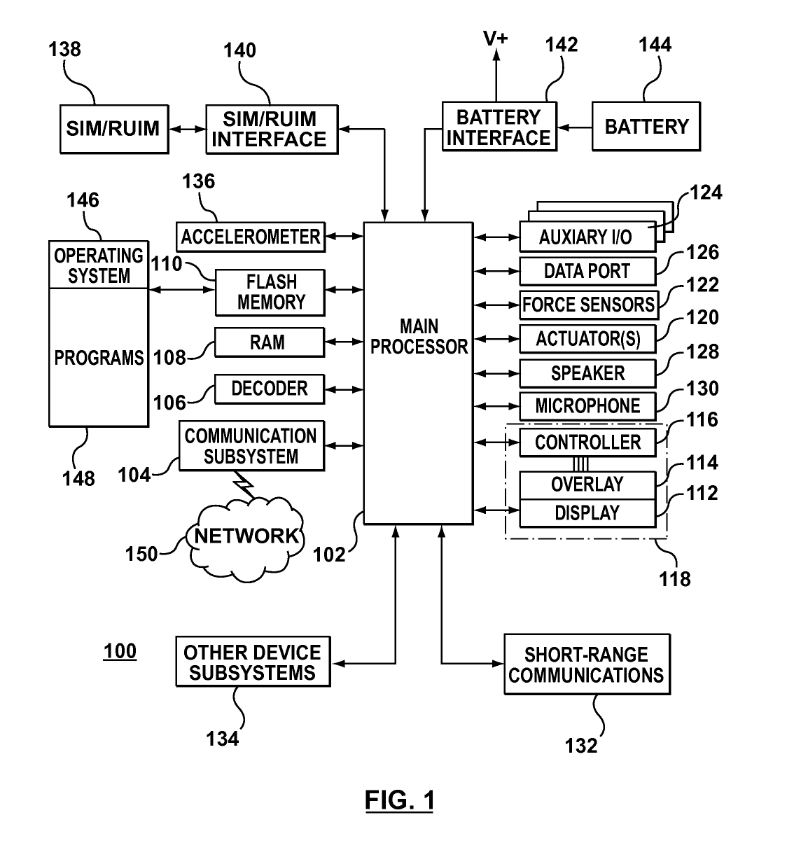

FIG. 1 shows a simplified block diagram of components of a portable electronic device 100. The portable electronic device 100 includes multiple components such as a processor 102 that controls the operations of the portable electronic device 100. Communication functions, including data communications, voice communications, or both may be performed through a communication subsystem 104. Data received by the portable electronic device 100 may be decompressed and decrypted by a decoder 106. The communication subsystem 104 may receive messages from and send messages to a wireless network 150.

The wireless network 150 may be any type of wireless network, including, but not limited to, data-centric wireless networks, voice-centric wireless networks, and dual-mode networks that support both voice and data communications.

The portable electronic device 100 may be a battery-powered device and as shown includes a battery interface 142 for receiving one or more rechargeable batteries 144.

The processor 102 also interacts with additional subsystems such as a Random Access Memory (RAM) 108, a flash memory 110, a display 112 (e.g. with a touch-sensitive overlay 114 connected to an electronic controller 116 that together comprise a touch-sensitive display 118), an actuator assembly 120, one or more optional force sensors 122, an auxiliary input/output (I/O) subsystem 124, a data port 126, a speaker 128, a microphone 130, short-range communications systems 132 and other device subsystems 134.

In some embodiments, user-interaction with the graphical user interface may be performed through the touch-sensitive overlay 114. The processor 102 may interact with the touch-sensitive overlay 114 via the electronic controller 116. Information, such as text, characters, symbols, images, icons, and other items that may be displayed or rendered on a portable electronic device generated by the processor 102 may be displayed on the touch-sensitive display 118.

The processor 102 may also interact with an accelerometer 136 as shown in FIG. 1. The accelerometer 136 may be utilized for detecting direction of gravitational forces or gravity-induced reaction forces.

To identify a subscriber for network access according to the present embodiment, the portable electronic device 100 may use a Subscriber Identity Module or a Removable User Identity Module (SIM/RUIM) card 138 inserted into a SIM/RUIM interface 140 for communication with a network (such as the wireless network 150). Alternatively, user identification information may be programmed into the flash memory 110 or performed using other techniques.

The portable electronic device 100 also includes an operating system 146 and software components 148 that are executed by the processor 102 and which may be stored in a persistent data storage device such as the flash memory 110. Additional applications may be loaded onto the portable electronic device 100 through the wireless network 150, the auxiliary I/O subsystem 124, the data port 126, the short-range communications subsystem 132, or any other suitable device subsystem 134.

In use, a received signal such as a text message, an e-mail message, web page download, or other data may be processed by the communication subsystem 104 and input to the processor 102. The processor 102 then processes the received signal for output to the display 112 or alternatively to the auxiliary I/O subsystem 124. A subscriber may also compose data items, such as e-mail messages, for example, which may be transmitted over the wireless network 150 through the communication subsystem 104.

For voice communications, the overall operation of the portable electronic device 100 may be similar. The speaker 128 may output audible information converted from electrical signals, and the microphone 130 may convert audible information into electrical signals for processing.

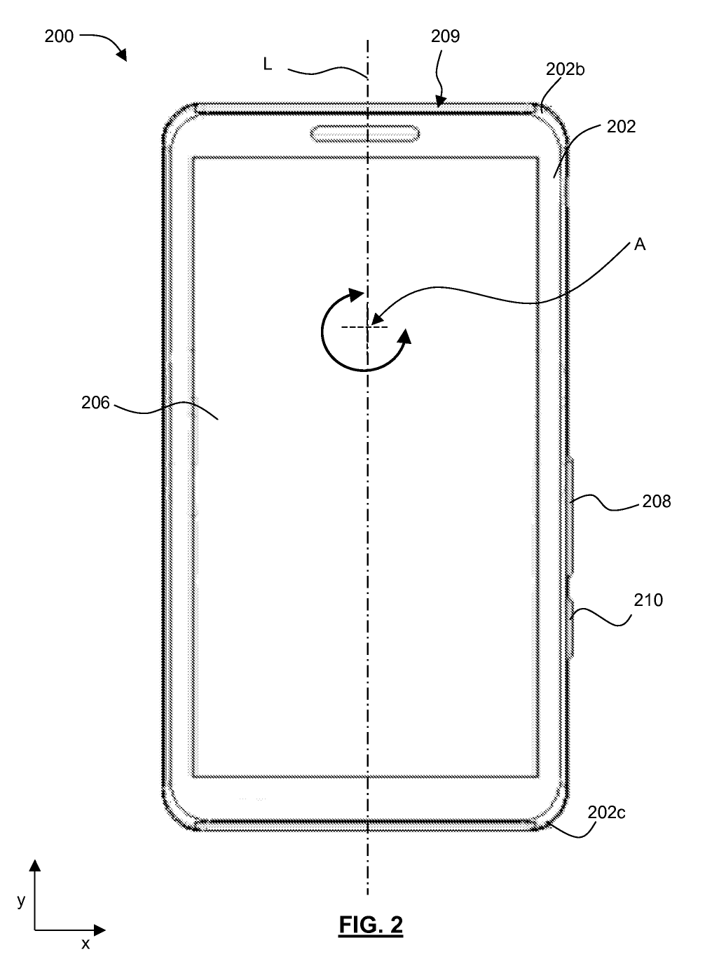

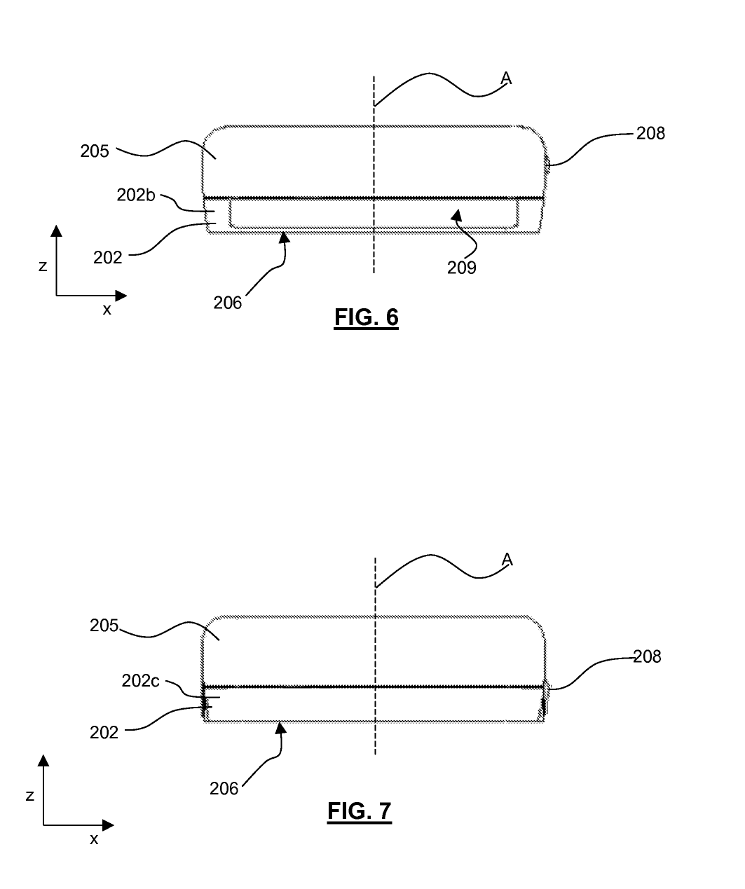

Turning now to FIGS. 2 to 7, illustrated therein is a portable electronic device 200 according to one embodiment. The portable electronic device 200 is a slidable and rotatable device and generally includes a first portion (shown here as a display portion 202), a second portion (shown here as a keypad portion 204), and a third portion (shown here as a slide portion 205) that is coupled to both the display portion 202 and keypad portion 204.

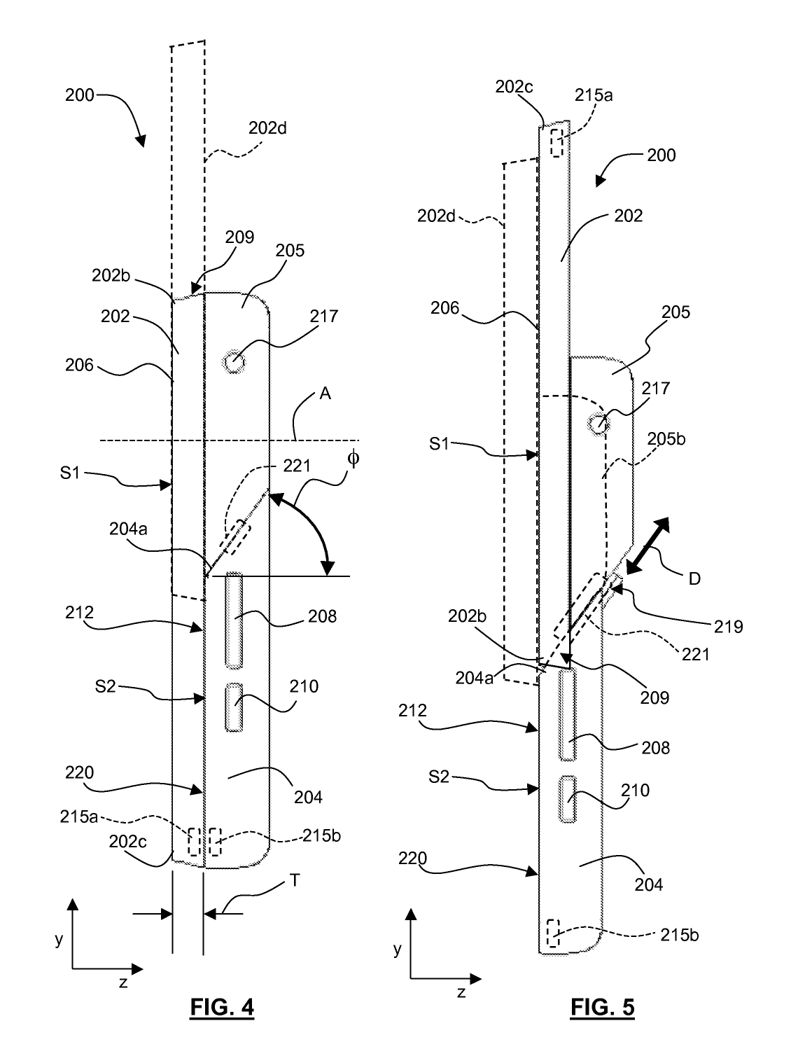

The display portion 202, keypad portion 204, and slide portion 205 are sized and shaped so that the display portion 202 can move between a “closed position” wherein the display portion 202 covers at least a portion of the keypad portion 204 (e.g. the display portion 202 covers a surface S2 of the keypad portion 204 as shown in FIG. 4) and the first surface S1 and second surface S2 are offset from each other or misaligned, and an “open position” wherein the surface S2 of the keypad portion 204 is exposed and a surface S1 of the display portion 202 is aligned with the surface S2 of the keypad portion 204 (as shown in FIG. 5).

In particular, the slide portion 205 and display portion 202 are rotatably coupled so that the display portion 202 may be rotated about a rotational axis A from the closed position (shown in FIG. 2) to a rotated position (indicated generally as 202d in FIG. 4). When the display portion 202 has moved to the rotated position, the surface S2 of the keypad portion 204 is at least partially exposed.

Furthermore, the slide portion 205 is slidably coupled to the keypad portion 204 so that when the display portion 202 is in the rotated position, the display portion 202 and slide portion 205 can slide in a slide direction D so that the surface S1 of the display portion 202 and the surface S2 of the keypad portion 204 can be aligned (as shown in FIG. 5). In effect, the display portion 202 may be “dropped down” (e.g. along the z-direction) so that the two surfaces S1 and S2 align or are generally coplanar.

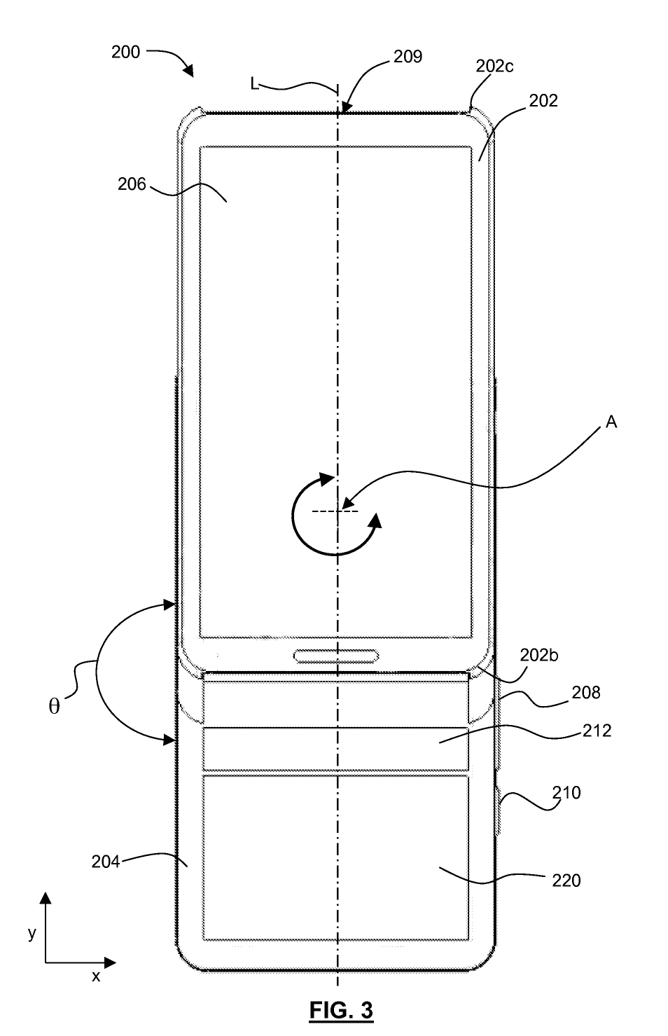

As shown in FIG. 3, the display portion 202 has been rotated about the rotation axis A through a rotation angle θ. In this embodiment, the rotational axis A and the rotational angle θ are selected so that the display portion 202 is generally aligned with a longitudinal axis L of the portable electronic device 200 in both the closed position (shown in FIG. 2) and the rotated position (shown in FIG. 3). In particular, the rotational axis A in this embodiment is located on the longitudinal axis L, and the rotational angle θ is about 180 degrees.

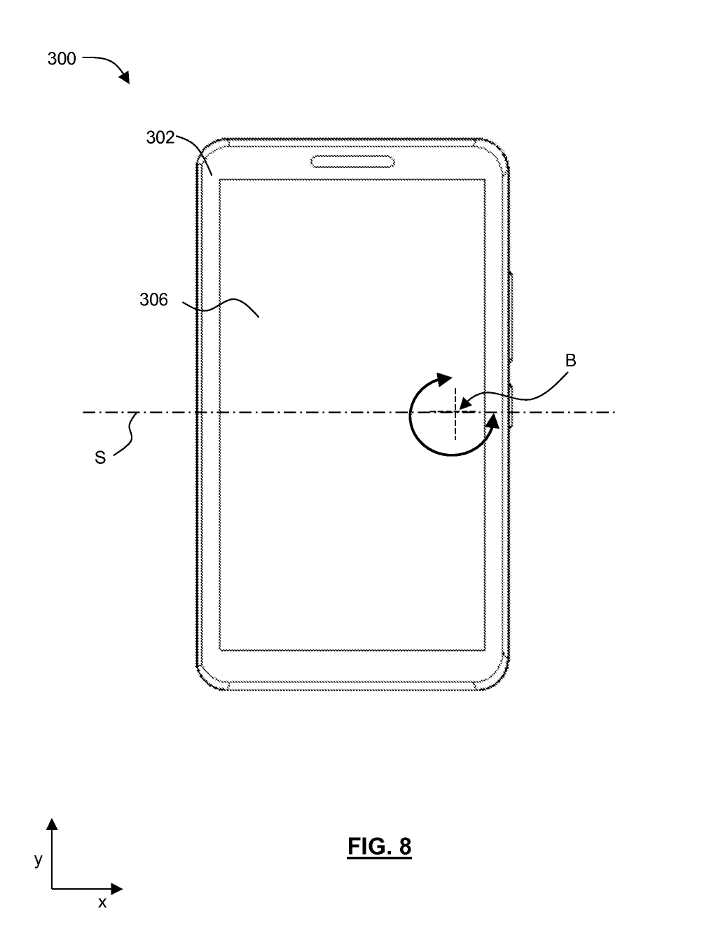

In other embodiments, the display portion 202 may be rotatably coupled to the slide portion 205 in other ways. For example, the rotational axis and the rotational angle may be selected so that the display portion 202 is generally aligned with a transverse axis S of the portable electronic device 200 in the rotated position (e.g. as shown in FIGS. 8 to 11 and described below).

The slide direction D has a component that extends in a direction that is normal to the surface S1 of the display portion 202 (e.g. along the z-axis). As shown, the slide direction D may be angularly offset from the z-direction by a slide angle φ (as shown in FIG. 4), which as shown may be greater than zero. Accordingly, as the display portion 202 and slide portion 205 move in the slide direction D, the display portion 202 and slide portion 205 will move along both the z-axis by an amount proportional to the cosine of the slide angle φ, and along a direction aligned with the longitudinal axis of the device 200 (e.g. the y-axis) by an amount proportional to the sine of the slide angle φ.

Generally, the slide direction D can be described as having a component aligned with the longitudinal direction of the device 200 (e.g. the y-component) and another component aligned with a direction that is normal to the surface S1 of the display portion 202 (e.g. the z-component).

Selecting a slide angle φ greater than zero may allow for easier mechanical coupling between the display portion 202, the keypad portion 204, and the slide portion 205. Furthermore, when the slide angle φ is greater than zero, an upward force on the display portion 202 (e.g. a user's thumb or finger pushing on the display portion 202 towards a top end of the device 200) when the display portion 202 is in the rotated position 202d will tend to push the display portion 202 in the slide direction D. This may make it easier for a user to fully open the portable electronic device 200.

In some embodiments the slide angle φ may be between 15 degrees and 75 degrees. In some embodiments the slide angle φ may be between 30 degrees and 60 degrees. In some embodiments the slide angle φ may be approximately 45 degrees.

In other embodiments, the slide angle φ may be less than zero (e.g. the slide angle φ may be negative).

As shown in FIG. 4, the display portion 202 has a thickness T. Accordingly, when moving the display portion 202 to the open position to align the first and second surfaces S1 and S2, the slide portion 205 moves along the z-direction by a distance approximately equal to T. This means that the slide portion 205 should be moved in the slide direction D by distance equal to the distance T divided by the cosine of the slide angle φ.

The display portion 202, keypad portion 204 and slide portion 205 may be coupled together using various techniques. For example, the keypad portion 202 and slide portion 205 may be rotatably coupled together so as to rotate about the rotation axis A. The position of the rotational axis A is selected so that when the display portion 202 is in the rotated position 202d, the surface S2 of the keypad portion 204 is exposed and the display portion 202 can be moved in the slide direction D into the open position. Furthermore, as shown, the rotational axis A may positioned along the longitudinal axis L of the device 200 so that the display portion 202 remains aligned with the keypad portion 204 in both the closed position and the rotated position.

The slide portion 205 and keypad portion 204 may be slidably coupled together using a slide mechanism 219, which may include interlocking slide rails for example. The slide mechanism 219 allows for relative movement between the slide portion 205 and the keypad portion 204 along the slide direction D so that the surfaces S1 and S2 of the display portion and keypad portion 204 can be aligned, but inhibits movement in other directions. In this embodiment, the slide mechanism 219 is inclined upwardly (from front to back of the device 200) so as to define the slide angle φ.

In some embodiments, the slide mechanisms 219 may have other configurations, for example, a tongue in groove arrangement that allows sliding movement between the keypad portion 204 and the slide portion 205.

In some embodiments, the slide mechanism 219 may include a biasing member (e.g. a linear spring, such as a compression or extension spring, or another biasing member). The biasing member may encourage the slide portion 205 and display portion 202 to move between one or more of the rotated position and the closed position. For example, a linear spring 221 in the slide mechanism 219 may be compressed when the portable electronic device 200 is in the closed position (see FIG. 4) and extended when the portable electronic device 200 is in the open position (see FIG. 5).

Similarly, a biasing member (e.g. a coiled spring) may be provided between the display portion 202 and the slide portion 205 to encourage the display portion 202 to move between one or more of the closed potion and the rotated position. For example, a coiled spring may be adapted to encourage rotation of the display portion 202 from the closed position to the rotated position.

In some embodiments, one or more locks or latches (e.g. mechanical locks, magnets, etc.) may be provided in one or more of the display portion 202, keypad portion 204 and slide portion 205 to help retain the portable electronic device in one or more of the closed position, the rotated position and the open position. For example, as shown in FIGS. 4 and 5, magnets 215a, 215b in the display portion 202 and the keypad portion 204 (respectively) may attract each other and help retain the device 200 in the closed position, but may not substantially interact with each other when the device 200 is in the open position.

When moving the display portion 202 from the closed position (shown in FIG. 2) to the open position (shown in FIG. 3), a user may rotate the display portion 202 around the rotation axis A so that the top end 202b and bottom end 202c of the display portion 202 are inverted. In some embodiments, this movement may be facilitated by a biasing member (e.g. a spring). Once the display portion 202 is in the rotated position 202d (e.g. so that the inverted top end 202b of the display portion 202 is clear of an edge of a corner 204a of the surface S2 of the keypad portion 204), the display portion 202 can then be moved in the slide direction D to align the surfaces S1 and S2.

In some embodiments, the movement in the slide direction D may be effected by the user pushing upwardly on the display portion 202 when in the rotated position 202d. In some embodiments, a biasing member (e.g. a spring) might at least partially assist moving the slide portion 205 along the slide direction D into the open position. Once in the open position, a locking mechanism (e.g. a latch or magnet) may help retain the portable electronic device 200 in the open position.

In some embodiments, the top end 202b of the display portion 202 may include a recessed portion 209 (shown in FIG. 2) adapted to facilitate clearance of the display portion 202 past the corner 204a of the keypad portion 204 when the device 200 is in the rotated position 202d.

When the user wants to move the portable electronic device 200 back to the closed position (e.g. to close the portable electronic device 200), the user may press the back of the slide portion 205, moving the display portion 202 and slide portion 205 along the slide direction D back into the rotated position 202d. The user may then rotate the display portion 202 about the rotational axis A back to the closed position. In some embodiments, biasing member(s) (e.g. a springs) may help facilitate closing of the portable electronic device 200, and one or more locks may be used to help retain the portable electronic device 200 in the closed position.

In some embodiments, the first and second surfaces S1 and S2 are “active” surfaces in that they may include one or more input or output devices (or both), such as display screens, buttons, etc. For example, the first surface S1 might include the surface of a touch screen display 206. Similarly, the second surface S2 may include the surface of a keypad 220, other input devices 212, or another portion of the keypad portion 204.

Aligning the “active” surfaces S1 and S2 when the portable electronic device 200 is open may be beneficial. For example, user interaction with the portable electronic device 200 may be improved as a user may be able to transition from engaging the first surface S1 (e.g. touching a touch screen display 206 using a finger), to performing engaging the second surface S2 (e.g. the input devices 212 or keypad 220) generally without encountering discontinuities, such as a lip or stepped portion.

While the portable electronic device 200 has been described with respect to a touch screen display 206 and a keypad 220, the portable electronic device 200 may include other input and output devices, and may have other configurations as will be appreciated from the following description of some other exemplary input and output devices.

In some embodiments, the display 206 could be an LCD display with touch screen capabilities. For example, the display 206 could be the display 118 as generally described above. In some other embodiments, the display 206 may not be a touch screen display.

The portable electronic device 200 may include other input devices, such as navigation keys or buttons, a physical or virtual keyboard, a trackpad, a trackball, multimedia keys, etc. For example, in this embodiment the keypad portion 204 includes one or more input devices 212, which could include an optical navigation module (e.g. a trackpad), buttons, such as a phone application button, a home screen button, etc. In some embodiments, these input devices may include optical sensors, mechanical buttons, “soft keys”, or various combinations thereof.

In some embodiments, the keypad portion 204 includes physical buttons 208 and 210 on a side of the keypad portion 204. In some embodiments, buttons 208, 210 could be used for navigation, volume control, or for other purposes. The portable electronic device 200 as shown also includes an audio jack 217 on the side of the slide portion 205, which may be used to couple the portable electronic device 200 to a speaker, a microphone, etc.

In some embodiments, the keypad 220 may include a plurality of alphanumeric keys for inputting data into and otherwise controlling the portable electronic device 200. In some embodiments, the keys may represent an alphabet and may be arranged with a standard keyboard layout (e.g. QWERTY, QWERTZ, DVORAK, etc.) or according to other particular patterns. In some embodiments, the keypad 220 could be a physical keypad 220 with mechanical keys. In other embodiments, the keypad 220 could be a touch screen with soft keys.

As shown in FIGS. 3 and 5, when the portable electronic device 200 is in the open position, the keypad 220 on the keypad portion 204 may be exposed for user access. As shown in FIGS. 2 and 4, when the portable electronic device 200 is in the closed position, the keypad 220 may be covered by the display portion 202. This may be beneficial as it may protect the keypad 220 when not in use, and may also inhibit keys from being pressed unintentionally when a user is carrying the portable electronic device 200 (e.g. in a pocket for example).

In some embodiments, the user may be able to perform functions on the portable electronic device 200 when the device 200 is closed, for example, by interacting with the accessible input devices (e.g. buttons 208, 210, the touch screen display 206, etc.). Then, when the device 200 is open, functions can be performed using other input devices, such as the input devices 212 and keypad 220.

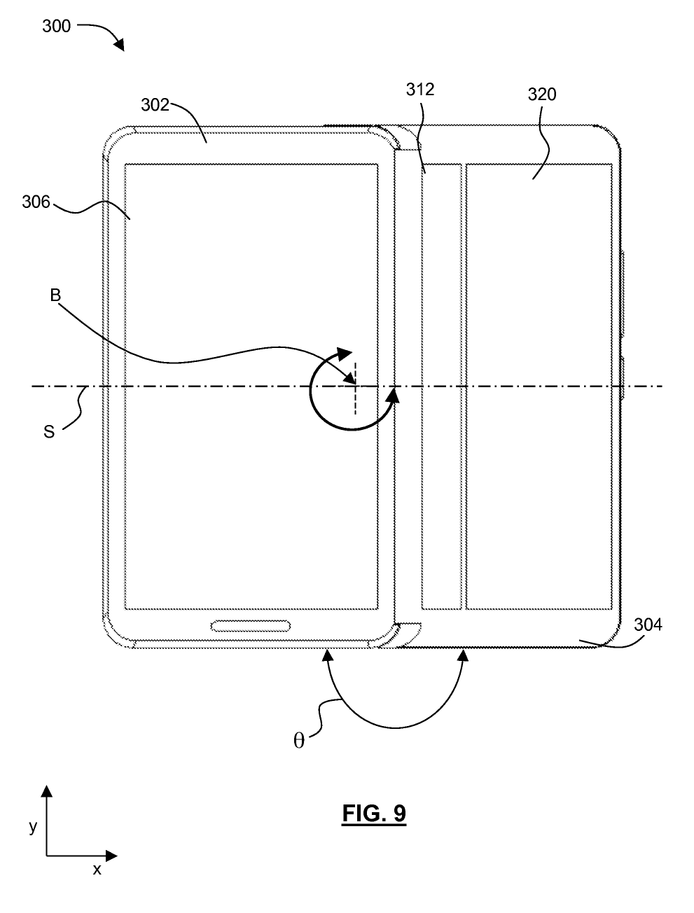

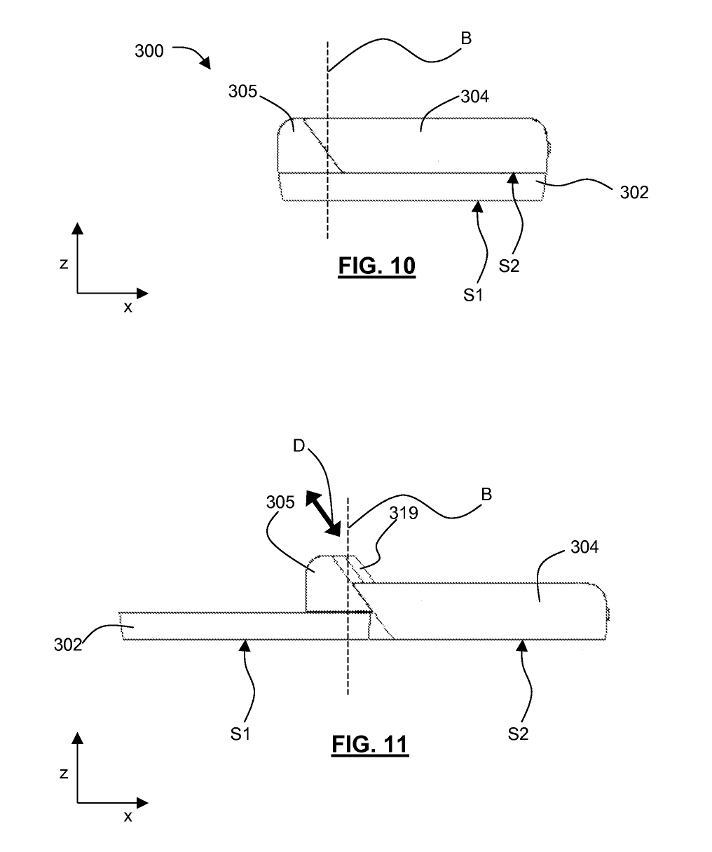

Turning now to FIGS. 8 to 11, illustrated generally therein is a portable electronic device 300 according to another embodiment. The portable electronic device 300 is generally similar to the portable electronic device 200 described above. In particular, the portable electronic device 300 includes a first portion (e.g. a display portion 302), a second portion (e.g. a keypad portion 304), and a third portion (e.g. a slide portion 305) that is coupled to both the display portion 302 and keypad portion 304 so that the display portion 302 can move between a closed position wherein the display portion 302 covers at least a portion of the keypad portion 304 (as shown in FIGS. 8 and 10), and an open position (as shown in FIGS. 9 and 11) wherein the keypad portion 304 is at least partially exposed and the surfaces S1, S2 of the display portion 302 and keypad portion 304 are aligned. In some embodiments, a display 306 may be a touch screen display and the keypad portion 304 may include input devices 312 and a keypad 320 with a plurality of keys.

However, in this embodiment the display portion 302 is adapted to rotate about a rotation axis B selected so that the display portion 302 is generally aligned with a transverse axis S of the portable electronic device 300. After rotating the display portion 302 into the rotated position, the display portion 302 can then be moved in a slide direction D (e.g. using a slide mechanism 319) so that the surfaces of the display portion 302 and keypad portion 304 can be aligned.

Accordingly, this portable electronic device 300 may be operated with the keypad 320 and display 306 in a “landscape” mode when in the open position (as opposed to the portable electronic device 200 which operates in a “portrait” mode when open).

At least some of the embodiments as described herein may provide one or more benefits. For example, by aligning the “active” surfaces S1 and S2 when the portable electronic device 200 is open, user interaction with the portable electronic device 200 may be improved. In particular, a user may be able to transition from engaging the first surface S1 (e.g. touching a touch screen display 206 using a finger), to performing engaging the second surface S2 (e.g. the input devices 212 or keypad 220) generally without encountering discontinuities, such as a lip or stepped portion. Furthermore, when the portable electronic device 200 is in the closed position, the keypad 220 may be covered by the display portion 202. This can protect the keypad 220 when not in use, and may also inhibit keys from being pressed unintentionally when a user is carrying the portable electronic device 200 for example.

In some other embodiments, there is provided a portable electronic device that can rotate to provide the display portion in both the longitudinal and transverse directions, so that the device can be selectively operated in either a landscape mode or portrait mode as desired.

While reference has been made herein to portable electronic devices wherein a first portion is a display portion, a second portion is a keypad portion, and a third portion is a slide portion, this is not meant to be limiting and other configurations are possible. For example, the first portion and second portion may both be touchscreen portions with no keypad. In other examples, the first portion may have a keypad and the second portion may include a display.

While the above description provides examples of one or more processes or apparatuses, it will be appreciated that other processes or apparatuses may be within the scope of the accompanying claims.

1. A portable electronic device, comprising:
a first portion having a first surface;
a second portion having a second surface; and
a slide portion coupled to the first and second portions;
wherein the first portion, second portion and slide portion are adapted so that the first portion can rotate between a closed position wherein the first portion at least partially covers the second surface, and a rotated position wherein the second surface is at least partially exposed, and wherein, when the first portion is in the rotated position, the first portion and slide portion can slide relative to the second portion along a slide direction to an open position in which the first surface and second surface are aligned.

2. The portable electronic device of claim 1, wherein the first portion is a display portion and includes a display.

3. The portable electronic device of claim 1, wherein the second portion is a keypad portion and includes a keypad.

4. The portable electronic device of claim 1, wherein, in the rotated position the first portion is aligned with a longitudinal axis of the portable electronic device.

5. The portable electronic device of claim 1, wherein, in the rotated position the first portion is aligned with a transverse axis of the portable electronic device.

6. The portable electronic device of claim 1, wherein the slide direction has a component aligned with a direction normal to the first surface.

7. The portable electronic device of claim 1, wherein the slide direction is inclined upwardly by a slide angle and has a component aligned with at least one of a longitudinal axis of the portable electronic device and a transverse axis of the portable electronic device.

8. The portable electronic device of claim 7, wherein the slide angle is between 15 and 75 degrees

9. The portable electronic device of claim 7, wherein the slide angle is between 30 and 60 degrees.

10. The portable electronic device of claim 1, wherein the second portion and slide portion are slidably coupled together using a slide mechanism.

11. The portable electronic device of claim 1, further comprising at least one biasing member for biasing the portable electronic device to at least one of the closed position, the rotated position, and the open position.

12. The portable electronic device of claim 11, wherein the at least one biasing member includes a spring.

13. The portable electronic device of claim 1, further comprising at least one locking device for retaining the portable electronic device in at least one of the closed position, the rotated position, and the open position.

14. The portable electronic device of claim 13, wherein the at least one locking device includes at least one magnet.

15. The portable electronic device of claim 1 wherein a top end of the first portion includes a recessed portion adapted to facilitate clearance of the first portion past the second portion when the device is in the rotated position.

16. A portable electronic device, comprising:
a first portion having a first surface;
a second portion having a second surface; and
a slide portion coupled to the first and second portions;
wherein the first portion, second portion and slide portion are adapted so that the first portion can rotate between a closed position wherein the first portion at least partially covers the second surface, and a rotated position wherein the second surface is at least partially exposed; and
wherein, when the first portion is in the rotated position, the first portion and slide portion can slide relative to the second portion along a slide direction to an open position in which the first surface and second surface are aligned,
wherein a top end of the first portion includes a recessed portion adapted to facilitate clearance of the first portion past the second portion when the device is in the rotated position.

17. The portable electronic device of claim 16, wherein, in the rotated position the first portion is aligned with a longitudinal axis of the portable electronic device.

18. The portable electronic device of claim 16, wherein, in the rotated position the first portion is aligned with a transverse axis of the portable electronic device.

19. The portable electronic device of claim 16, wherein the slide direction is inclined upwardly by a slide angle and has a component aligned with at least one of a longitudinal axis of the portable electronic device and a transverse axis of the portable electronic device, so as to define a slide angle.

20. A method of opening a portable electronic device, comprising:
providing a first portion having a first surface, a second portion having a second surface, and a slide portion coupled to the first and second portions;
rotating the first portion between a closed position wherein the first portion at least partially covers the second surface and a rotated position wherein the second surface is at least partially exposed; and
from the rotated position, sliding the first portion and slide portion relative to the second portion along a slide direction to an open position in which the first surface and second surface are aligned.
